(19) United States
(12) Patent Application Publication
(10) Pub. No.: US 2016/0013340 A1
(43) Pub. Date: Jan. 14, 2016

(54) COAXIAL LITHOGRAPHY

(71) Applicant: NORTHWESTERN UNIVERSITY, Evanston, IL (US)

(72) Inventors: Chad A. Mirkin, Wilmette, IL (US); Tuncay Ozel, Evanston, IL (US); Gilles R. Bourrent, Chicago, IL (US)

(21) Appl. No.: 14/691,711

(22) Filed: Apr. 21, 2015

Related U.S. Application Data
(60) Provisional application No. 62/000,861, filed on May 20, 2014.
(60) Provisional application No. 61/981,921, filed on Apr. 21, 2014.

(51) Int. Cl. H01L 31/0352; H01L 31/18; C25D 1/04

(52) U.S. Cl. CPC H01L 31/035227; C25D 1/04; H01L 31/1892

(57) ABSTRACT

Methods for radial control of nanorods using a coaxial lithographic technique are disclosed, as are nanorods prepared by these methods and applications of these nanorods in energy storage, photocatalysis, and solar energy conversion.

### CROSS REFERENCE TO RELATED APPLICATIONS

The benefit under 35 U.S.C. §119(e) of U.S. Provisional Application No. 61/981,921, filed Apr. 21, 2014, and U.S. Provisional Application No. 62/000,861, filed May 20, 2014 is claimed, the disclosures of which are each incorporated herein by reference in their entirety.

### STATEMENT OF US GOVERNMENT SUPPORT

This invention was made with government support under DE-SC0000989 awarded by the Department of Energy; N00244-09-1-0012 and N00244-09-1-0071 awarded by the Naval Supply Fleet Logistics Center San Diego (NAVSUP FLC SD); FA9550-09-1-0294 awarded by the Air Force Office of Scientific Research; N00014-11-1-0729 awarded by the Office of Naval Research; and DMR-1121262 awarded by the National Science Foundation. The government has certain rights in the invention.

### BACKGROUND

High-resolution lithographic tools, enabling excellent control of material composition and geometry at the nanoscale, are necessary to manipulate and tailor the properties of metals and semiconductors (1-3). Research areas such as solar energy conversion, energy storage and nanophotonics are highly dependent on the development of these technologies (1, 3-6). For instance, the use of coaxial nanowires composed of optically active p- and n-type semiconductors can drastically improve the conversion of photons into electrical and chemical energy (6-9). This is due to their high heterojunction area and appropriate energy band bending, which allows for efficient electron-hole separation, while minimizing undesired electron-hole recombination (9). Likewise, metallic nanostructures can confine and intensify light within nanoscale volumes through localized surface plasmon resonances, a phenomenon that has been used to enhance light emission and absorption within semiconductors (2-5, 8, 10). This has allowed researchers to explore novel pathways for energy harvesting and molecular sensing and has been proposed as a promising approach for improving the conversion of solar light into electrical energy (4, 6, 11). In particular, plasmon-sensitized solar cells and water-photosplitters in which plasmonic structures directly transfer energy or charge carriers into the semiconducting materials, offer the possibility of enhanced efficiencies (12-14). However, the integration of these architectures at the nanowire level is clearly hindered by the current synthetic capabilities. The ability to create semiconductor nanowires with well-defined plasmonic structures that improve the photovoltaic response and do not interfere with the electron-hole flow requires precise control over the size and composition of both the core and the shell components. This is not possible with current lithographic techniques.

Methods such as photolithography, electron-beam lithography, dip-pen nanolithography, nanoimprint lithography, and on-wire lithography have all been successfully used to prepare complex functional nanoscale systems (3, 15-17). These lithographic systems suffer, however, from one significant limitation: poor control over the radial dimension. Such control is essential to synthesize plasmonically and catalytically active well-defined metallic nanostructures in and around coaxial semiconductor nanowires, which could be foundational components for the development of next-generation photovoltaic and photocatalytic systems (4, 18). To date, state-of-the-art vapor liquid solid (VLS) synthesis has been a promising way to make coaxial semiconductor nanowires (8, 19, 20). However, this method is limited to the deposition of inorganic semiconductors, lacks the ability to couple them to well-defined metallic structures, and does not allow any control over the shell length and location. In contrast to VLS syntheses, electrochemical deposition within anodic aluminum oxide (AAO) templates, pioneered by Martin and Moskovits (21, 22), and later expanded by Natan and Keating (23, 24), offers a direct route to grow multi-segmented metallic and semiconducting nanowires with great control over the composition and dimensions of each segment (10, 17, 21-28). The use of multi-segmented nanowires to generate nanoscale gaps between metal nanowires was developed further by our group and others (17, 26-29). The on-wire lithography technique, developed in our laboratory, extended these concepts further to generate one-dimensional arrays of metal nanoparticles with nanometer resolution (17, 27). However, while all of these techniques allow good geometrical control in the axial dimension of the nanowire, they do not provide any control in the radial dimension. Provided herein is a high-throughput and widely compatible method, termed coaxial lithography (COAL), for producing coaxial nanowires with sub-10 nm lithographic resolution in both linear and radial dimensions. COAL allows for the synthesis of multi-compositional coaxial core/shell, core/multi-shell and asymmetric nanowires via templated electrochemical deposition and selective wet-chemical etching processes (FIG. 1). To demonstrate the lithographic control over the shell component, metal nanorings of varying composition (gold, silver, platinum, nickel and palladium), position and length (from 10 nm to a few microns) around a wide variety of metal and semiconductor cores (conjugated polymers, metal oxides and metal chalcogenides) of different diameters (from 40 to 400 nm) were synthesized. Successful integration of plasmonically active Au nanorings within P3HT core/CdSe shell radial junctions is presented. The plasmonic nanoring does not block the electron-hole flow and is optically active as shown by the strongly modified photoresponsitivy of the resulting nanowires. Thus, a need exists for controlled synthesis of nanorods, including control and variability of the radial properties along the nanorod.

### SUMMARY

Provided herein are nanorods comprising a first segment and a second segment, the first segment comprising a metal and the second segment comprising (a) a core having a diameter smaller than the first segment diameter, and optionally (b) a shell around at least a portion of the core, the first segment in contact with the core. The shell can be absent. The shell length can be the same as the core length, or longer than the core length. The shell can abut the first segment. The shell can be separated from the first segment by a gap. The shell can form a ring around the core and have a ring length, said ring length shorter than the core length. The nanorod can have at least two rings around the core, each ring on the core separate by a ring gap. The ring gap can be about 3 nm to about 20 nm. Each ring can comprise the same material. Each ring can comprise a metal. The metal can be gold, nickel, platinum, silver, or a mixture thereof. In some cases, one ring comprises a first ring material and another ring comprises a second ring material. In various cases, the first ring material comprises gold and the second ring material comprises silver, platinum, or nickel. In some cases, at least one ring comprises a metal. In some cases, the ring length is about 10 nm to about 100 nm. The first segment can have a diameter of about 50 to about 500 nm, about 50 to about 300 nm, or 200 nm to about 500 nm. The core can have a diameter of about 35 to about 150 nm. The shell and core together can have a diameter of about 50 to about 400 nm, or about 200 nm to about 700 nm. The core can comprise a semiconductor, such as, for example, cadmium selenide, zinc selenide, cadmium telluride, zinc telluride, cadmium-tellurium selenide, copper-indium selenide, copper oxide, copper sulfide, silicon, germanium, compounds and alloys of silicon and germanium, gallium arsenide, gallium phosphide, gallium nitride, cadmium sulfide, zinc sulfide, titanium dioxide, zinc oxide, tungsten oxide, molybdenum oxide, manganese oxide, titanium sulfide, and mixtures thereof. The core can comprise a conjugated polymer, a metal oxide, a metal chalcogenide, or a mixture thereof. The core can comprise polythiophene, polypyrrole, titanium dioxide, manganese oxide, cadmium selenide, polyaniline, nickel, or a combination thereof. The core can comprise poly(3-hexylthiophene-2,5-diyl). The shell can comprise nickel, gold, silver, platinum, palladium, or a mixture thereof.

The nanorods can further comprise a third segment, the second segment separating the first segment and the third segment. The third segment can comprise a metal. The third segment diameter can be the same as, larger, or smaller than the first segment diameter.

The nanorods can further comprise a second shell over the core and shell of the second segment. The second shell can abut the third segment. The second shell can comprise a metal or a non-metal.

Also provided herein are methods of making a nanorod as described. The method can comprise depositing the first segment onto a template using electrochemical deposition (ECD), and controlling the length of the first segment by monitoring the amount of charge passed during the electrochemical deposition; depositing the core of the second segment using ECD, and controlling the length of the core by monitoring the amount of charge passed during the ECD; optionally depositing the shell using ECD; optionally repeating one or more of these steps; optionally widening the template prior to the depositing step; and dissolving the template to form the nanorod.

Further provided are uses of the disclosed nanorods, e.g., as a semiconductor, as an energy storage device, in solar energy conversion, in photovolataics, or in photocatalysis.

### BRIEF DESCRIPTION OF FIGURES

FIG. 1. Coaxial Lithography. a, Scheme illustrating the geometrical and compositional parameters that can be controlled by COAL: diameters (d, d′ and d″: from 20 nm to 400 nm), segment lengths (s, s′ and s″: from 8 nm to few microns), and compositions (polymers: PANI, PPy, PTh, P3HT; metals: Au, Ag, Ni, Pt and Pd; inorganic semiconductors: MnO2, CdSe and CdS). b, Scheme illustrating the initial synthetic steps of COAL: electrochemical deposition within the AAO membrane of a metal segment, followed by deposition and shrinking of a polymer segment under vacuum. c, The following steps for generating metal rings around a polymeric core: deposition of a multi-segmented shell (Au and Ni alternating) around the polymer segment, dissolution of the AAO template and etching of the sacrificial shell segment (Ni in this sample). STEM images in SE (secondary electrons) and ZC (z-contrast) modes show typical nanowires before (left) and after etching (right) the sacrificial Ni shell to generate Au rings (outer diameter: 340 nm) around a polypyrrole core (diameter: 280 nm). Scale bars are 2 μm, 500 nm, and 500 nm, respectively. d, Alternative following steps used to control the shell diameter via pore-widening. This allows for the synthesis of core/shell/shell nanowires, as shown by the STEM images of a PANI core/Au ring/Ni shell nanowire composed of segments that have three different diameters. Scale bar is 250 nm.

FIG. 2. Generalization of COAL to inorganic cores. (A) Scheme illustrating the modified synthesis steps. From left to right: dissolution of the PANI core, etching of the sacrificial segments within the AAO, deposition of the core, dissolution of the AAO template. STEM images and elemental maps of (B) multiple Au rings around MnO₂ core (MnO₂ diameter: 65 nm; elemental map: alternating Mn and Au), (C) single Au ring around a CdS core (CdS diameter: 180 nm), and (D) rings composed of Au, Ag, Pt, Pd around a Ni core (Ni diameter: 190 nm). Scale bars are 200 nm.

FIG. 3. Integration of a plasmonic gold ring within a hybrid junction composed of an organic p-type core (P3HT) and an inorganic n-type shell (CdSe). (A) Scheme illustrating the modified synthesis steps. From left to right: dissolution of the PANI core, etching of the sacrificial segments within the AAO, deposition of the P3HT core, pore widening step, growth of the CdSe shell around the P3HT core and the Au ring, deposition of the top Au segment and dissolution of the AAO template. (B) SEM image, STEM image, and elemental maps of the P3HT core/CdSe shell nanowires with an Au ring. Scale bar is 100 nm for all of the images. (C) Comparison of the average Iₒₙ/I_{off} ratios as a function of wavelength of the nanowires with (circles) and without a ring (triangles). Three nanowires were measured in each case (with and without a ring). The error bars are the standard errors of the experimental measurements due to the nanowire photoresponse disparity under the same experimental conditions. (D) Simulated electric-field intensity maps of the metal segments (for the nanowire shown in B), without (left image) and with (right image) a ring, recorded at 532 nm (logarithmic scale). The maps were generated using an excitation source polarized in the direction parallel to the longitudinal axis of the nanowires. The dotted line corresponds to the location of the semiconductor segments.

FIG. 4. Polyaniline (PANI) core with 3 Au rings of different lengths. (a-c) Electron microscopy images of Ni/Au/PANI core-Ni/Au rings nanowires with Au rings of different lengths (35, 75 and 160 nm). (a) z-contrast and (b) SE mode images of 2 wires, scale bars: 200 nm. (c) Large scale z-contrast image showing a collection of nanowires, scale bar: 1 μm.

FIG. 5. Poly(3-hexylthiophene) (P3HT) core with 2 Au rings. SEM image of Ni/Au/P3HT core-Au rings nanowires. Scale bar: 1 μm. Length of the Au rings is around 130 nm.

FIG. 6. Polythiophene core with 4 Au rings. SEM image of polythiophene nanowires (40 nm diameter) with four gold rings (outer diameter: 75 nm, inner diameter: 40 nm). Scale bar: 500 nm.

FIG. 7. SEM image of free Au rings, released in solution by dissolving the polyaniline core with HNO₃. Ring outer diameter: 400 nm, inner diameter: 300 nm. Scale bar: 400 nm.

FIG. 8. The location of the Au rings is preserved inside the AAO membrane. (a) Top-view SEM image of Au tubes after removal of the PANI core and the AAO membrane, scale bar: 2 μm. (b) Cross-section SEM image showing that the ring location is preserved inside the membrane after dissolution of the PANI core and the Ni sacrificial rings. Scale bar: 200 nm.

FIG. 9. Sub-10 nm resolution achieved by COAL. (a) TEM image of a MnO₂ core-Au ring/Pt ring nanowire with a 8 nm thick Pt ring. Scale bar: 100 nm. (b) Large scale image showing a collection of the Ni/Au/MnO₂ core-Au ring/Pt ring nanowires (ring outer diameter: 80 nm, ring inner diameter: 40 nm).

FIG. 10. Typical current-voltage curves of Au/P3HT core-Au ring-CdSe shell/Au nanowires used for the plasmon-enhanced photocurrent measurement (FIG. 3).

FIG. 11. Control over the inner diameter. STEM images of polyaniline core/Ni shell nanowires without (a) and with (b) thinning treatment prior to the shell deposition.

FIG. 12. Smallest nanoring. STEM image of a Au nanoring around a P3HT core.

FIG. 13. Control over the outer diameter. STEM images of four concentric gold nanorings with increasing diameters around a polymer core without (left) and with (right) Ni segments. Scale bar equals to 100 nm.

FIG. 14. P3HT core/CdSe shell nanowires (no ring). (a) ZC STEM image of a typical P3HT core-CdSe shell nanowire (no ring) that was used in the photocurrent measurements shown in FIG. 3c). (b) Identical ZC STEM image. The blue dotted line shows the location of the CdSe shell and the orange dotted line shows the P3HT core.

FIG. 15. EDS maps of the P3HT core-Au ring-CdSe shell nanowire shown in FIG. 3b. (a) (Left) Scheme, ZC and SE mode STEM images of the P3HT core-Au ring-CdSe shell nanowire shown in FIG. 3b. (Right) Scheme and typical SE mode STEM image of the nanowires after etching of the CdSe shell with concentrated nitric acid, revealing the polymeric P3HT core. (b) EDS maps of the nanowire before etching the CdSe shell. Au Lα1 line at 9.712 keV (integration: 9.726 to 10.042 keV), Cd Lα1 line at 3.133 keV (integration: 3.010 to 3.256 keV): Se Lα1 line at 1.379 keV (integration: 1.275 to 1483 keV): sulfur Kα line at 2.307 keV (integration: 2.193 to 2.421 keV). It is clear that the S signal is located on the P3HT core and on the Au segments because of the overlap between the Au Mβ,γ lines (2.204 and 2.410 keV, respectively, not used for the mapping of Au) and the sulfur Kα line at 2.307 keV.

FIG. 16 (A-D). Schemes of formation of nanowires. 16A is a general scheme showing the synthesis of metal nanorings around an organic core. Blue: organic core. Yellow: target material (Au). Grey: sacrificial material (Ni). Ag, Ni and then Au were successively deposited within the AAO membrane. 16B shows the control over the segment diameter obtained via pore widening. Blue: organic core. Yellow: inorganic material 1 (Au). Grey: inorganic material 2 (Ni). 16C shows a general scheme of COAL: blue=sacrificial organic core (PANI); purple=any conductive material; yellow: target material (Au); grey: sacrificial material (Ni). 16D shows a modified COAL process to generate metal nanorings within core-shell nanowires. Blue: sacrificial PANI core. Yellow: target material (Au). Grey: sacrificial material (Ni). Green: organic semiconductor (P3HT). Red: inorganic semiconductor shell (CdSe).

### DETAILED DESCRIPTION

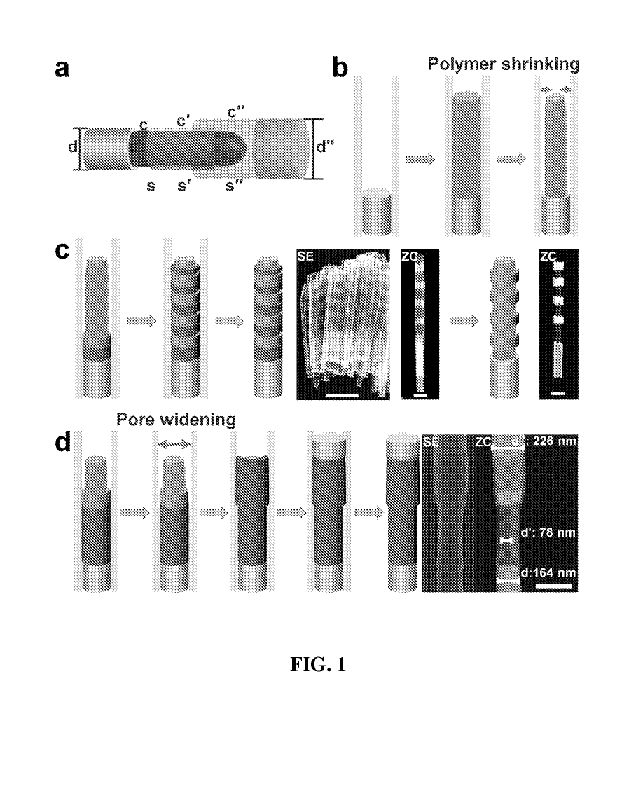

COAL involves the sequential electrodeposition of conductive materials within AAO membranes that have different mechanical and chemical stabilities (FIG. 1a). Coaxial nanowires are synthesized by inducing the radial contraction of electropolymerized polymers within the AAO pores. This leaves room for the subsequent growth of a shell around the polymer segment (FIG. 1b) (30). Multi-segmented shells composed of materials with varying reactivities towards wet-chemical etching (such as gold-nickel) are grown around the polymeric core by sequential electrochemical steps. Following the dissolution of the AAO membrane, subsequent etching of the sacrificial segment (nickel) generates coaxial nanowires composed of a polymeric core and a striped shell (gold) as shown in FIG. 1b (images were taken in the secondary electron (SE) mode and high-angle annular dark-field imaging z-contrast (ZC) mode of a scanning transmission electron microscope (STEM)). The dimensions of the negative and positive shell features are programmed by the thickness of the different segments (nickel-gold), which is electrochemically controlled with nanometer resolution. This approach is compatible with a wide variety of polymeric cores (i.e. polypyrrole, polyaniline, polythiophene, poly(3-hexylthiophene)). The high yield of this method is illustrated by large-scale electron microscopy images (FIG. 1b), showing core/shell nanowires (300 nm in diameter) composed of a polypyrrole core and multiple Au/Ni rings. Typical standard deviations in segment lengths are 14% for nickel and 10% for gold, with more than 80% of the nanowires having the same number of rings. Size distributions of the inner and outer diameters are typically 15-20%, mostly due to the dispersity of the AAO template pores. The structure of the gold rings is verified by the dissolution of the polymeric core, which results in the release of intact Au nanorings. Although the rings produced are not perfectly circular, their shape (i.e. complete versus crescent-like) is very homogenous within a given sample, and depends on the ring diameter (controlled by the diameter of the AAO pores). On average, for ring inner diameters larger than 70 nm, complete rings are formed (yield >90%). However, for ring inner diameters less than 50 nm, a mixture of complete rings and crescent-like nanostructures result. As the pore diameter gets smaller, the polymer core adheres more strongly to the AAO pore, preventing the deposition of complete shells.

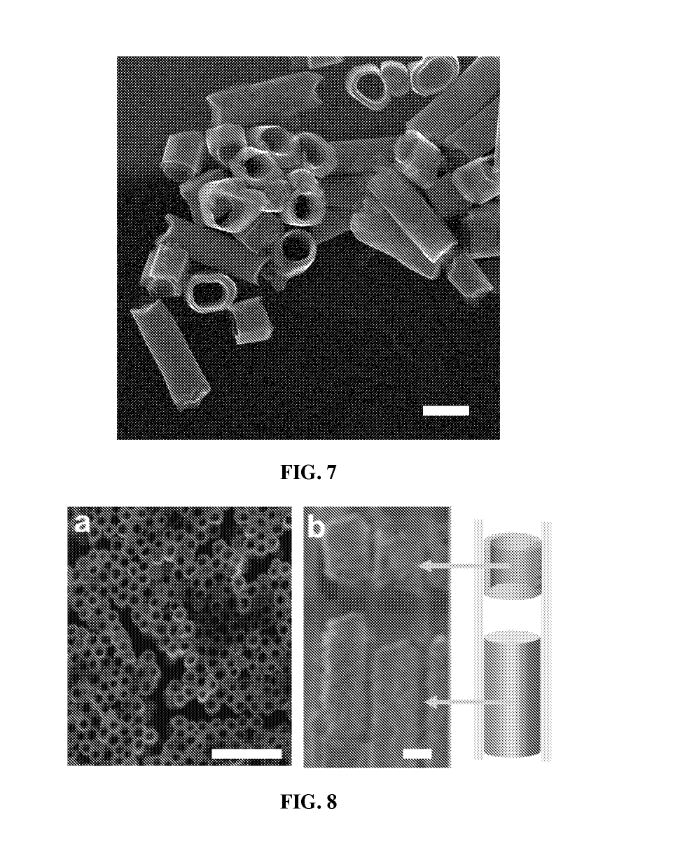

To demonstrate this geometric control, the electron microscopy images of a polyaniline core (d=100 nm) with three Au rings (d=140 nm) of different lengths (35 nm, 75 nm, and 160 nm) are shown in FIG. 4. The formation of full rings is verified by the dissolution of the polymeric core to release free Au rings in solutions, as shown in FIGS. 7 and 8. Additionally, the diameter of the shell segment can be increased via an additional pore widening step with the use of a mild NaOH aqueous solution. This allows for the synthesis of coaxial nanowires with multiple shells, as depicted in FIG. 1b showing a nanowire with core/shell/shell segments of three different diameters (78, 164 and 226 nm, respectively).

In contrast to VLS syntheses, electrochemical deposition within templates, e.g., anodic aluminum oxide (AAO) templates, offers a direct route to grow multi-segmented metallic and semiconducting nanorods with control over the composition and dimensions of each segment.

Provided herein is use of this technique for controlling the nanorod geometry in the radial direction. Described herein is a high-throughput and widely compatible method for producing coaxial nanorods with sub-10 nm lithographic resolution in both linear and radial dimensions. This method, termed Coaxial Lithography (COAL), allows the fabrication of nanorods composed of multiple shells with unprecedented control in terms of position and dimension of each component. COAL allows for the fabrication of multi-compositional coaxial core/shell, core/multi-shell and asymmetric nanorods via templated electrochemical deposition and selective wet-chemical etching processes.

To demonstrate the lithographic control over the shell component, metal nanorings of varying composition (non-limiting examples being gold, silver, platinum, nickel and palladium), position and length (from 10 nm to microns) around a wide variety of metal and semiconductor cores (conjugated polymers, metal oxides and metal chalcogenides) of different diameters (from 35 to 400 nm) have been fabricated. Moreover, integration of plasmonic nanorings within p-n type core-shell semiconductor nanowires demonstrates the potential of this new synthetic technique to redefine nanowire fabrication. To evaluate the scope of architectural control over the core and shell components, metal nanorings of varying composition (gold, silver, platinum, nickel, and palladium), position, and length (from 8 nm to a few microns) around a wide variety of metal and semiconductor cores (conjugated polymers, metal oxides, and metal chalcogenides) of different diameters (from 20 to 400 nm) were synthesised and characterised. Furthermore, the use of COAL to successfully integrate plasmonically active Au nanorings within poly-3-hexylthiophene (P3HT) core/CdSe shell radial junctions is described. Importantly, the plasmonic nanorings do not block the electron-hole flow within these structures and are optically active as shown by the modified photoresponse of the resulting nanowires.

Coaxial nanorods composed of radial heterojunctions are superior to their planar counterparts and are therefore now being investigated for a wide variety of applications, such as solar energy conversion, energy storage and nanophotonics. Prior to the methods and materials disclosed herein, the intrinsic limitations of conventional lithographic techniques have drastically limited the range of multi-compositional nanowires that can be made. Post-modification on pre-synthesized nanorods has been the only way to generate coaxial nanorods, offering no control over both the length and location of the shell along the nanorod. For example, the ability to tune the shell composition along the rod axis to generate asymmetric nanorods, still remains a synthetic challenge. Provided herein is a high-throughput method combining templated electrochemical synthesis and lithography for fabricating coaxial nanorods with sub-10 nanometer resolution in both linear and radial dimensions. Provided herein is the synthesis of various combinations of coaxial nanorods composed of, for example, metals, metal oxides, metal chalcogenides and conjugated polymers. In particular, provided herein is the ability to synthesize catalytic and plasmonic metal nanorings around and inside semiconductor nanorods.

### Nanorods Prepared by COAL

COAL involves the sequential electrodeposition of conductive materials within AAO membranes that have different mechanical and chemical stabilities (FIG. 1a). Coaxial nanowires are synthesized by inducing the radial contraction of electropolymerized polymers within the AAO pores. This leaves room for the subsequent growth of a shell around the polymer segment (FIG. 1b). Multi-segmented shells composed of materials with varying reactivities towards wet-chemical etching (such as gold-nickel) are grown around the polymeric core by sequential electrochemical steps. Following the dissolution of the AAO membrane, subsequent etching of the sacrificial segment (nickel) generates coaxial nanowires composed of a polymeric core and a stripped shell (gold, FIG. 1b). The dimensions of the negative and positive shell features are programmed by the thickness of the different segments (nickel-gold), which is electrochemically controlled with nanometer resolution. As shown in FIG. 1b, this approach is compatible with a wide variety of polymeric cores (i.e. polypyrrole, polyaniline, polythiophene, poly(3-hexylthiophene)). The high yield of this method is illustrated by electron microscopy images (FIG. 1b), showing core-shell nanowires (300 nm in diameter) composed of a polypyrrole core and multiple Au/Ni rings. Typical standard deviations in segment lengths are about 1-10% for nickel and 1-15% for gold. After sacrificial etching, the dimensions and locations of the gold rings are preserved (std 1-10%), generating semiconducting nanowires containing plasmonic Au nanorings at the desired locations and with precise dimensions. To demonstrate this geometrical control, the electron microscopy images of a polyaniline core with four Au rings of different lengths is shown in FIG. 1d. Additionally, the diameter of the shell segment can be increased via an additional pore widening step with the use of a mild NaOH aqueous solution (route II). This allows for the synthesis of coaxial nanowires with multiple shells (route II), as depicted in FIG. 1b showing a nanowire with core/shell/shell segments of 3 different diameters (78, 164 and 226 nm, respectively).

Thus, disclosed herein are nanorods comprising a first segment and a second segment, the first segment comprising a metal and the second segment comprising a core having a diameter smaller than the first segment diameter, and optionally a shell around at least a portion of the core. In some cases, the second segment does not have a shell around the core of the second segment. The nanorods can optionally comprise a third segment, the third segment separated from the first segment by the second segment.

The first segment metal can be one or more of gold, silver, platinum, palladium, or nickel. The metal is deposited into a template in a controlled fashion such that the length of the first segment can be controlled. For example, with ECD, the amount of current used dictates the amount of metal deposited into the template. As such, the length of the first segment is controlled to a desired length. The length can be 2 nm to 1 μm, 2 nm to 500 nm, 2 nm to 300 nm, 2 nm to 250 nm, 2 nm to 200 nm, 2 nm to 150 nm, 2 nm to 100 nm, 2 nm to 75 nm, 2 nm to 60 nm, 2 nm to 50 nm, 2 nm to 40 nm, 2 nm to 30 nm, 2 nm to 25 nm, 2 nm to 20 nm, 2 nm to 15 nm, 10 nm to 1 μm, 10 nm to 500 nm, 10 nm to 300 nm, 10 nm to 250 nm, 10 nm to 200 nm, 10 nm to 150 nm, 10 nm to 100 nm, 10 nm to 75 nm, 10 nm to 60 nm, 10 nm to 50 nm, 10 nm to 40 nm, 10 nm to 30 nm, 10 nm to 25 nm, 10 nm to 20 nm, 10 nm to 15 nm, 30 nm to 300 nm, 30 nm to 250 nm, 30 nm to 200 nm, 30 nm to 150 nm, 30 nm to 100 nm, 30 nm to 75 nm, 30 nm to 50 nm, 30 nm to 40 nm. The diameter of the first segment can be 10 nm to 500 nm, 10 nm to 400 nm, 10 nm to 300 nm, 10 nm to 250 nm, 10 nm to 200 nm, 10 nm to 150 nm, 10 nm to 100 nm, 10 nm to 75 nm, 10 nm to 60 nm, 10 nm to 50 nm, 10 nm to 40 nm, 10 nm to 30 nm, 10 nm to 25 nm, 10 nm to 20 nm, 10 nm to 15 nm, 30 nm to 200 nm, 30 nm to 150 nm, 30 nm to 100 nm, 30 nm to 75 nm, 30 nm to 50 nm, 30 nm to 40 nm, 100 nm to 1 micron, 100 nm to 900 nm, 100 nm to 800 nm, 100 nm to 700 nm, 100 nm to 600 nm, 100 nm to 500 nm, 100 nm to 400 nm, 100 nm to 300 nm, 100 nm to 200 nm, 200 nm to 1 micron, 200 nm to 900 nm, 200 nm to 800 nm, 200 nm to 700 nm, 200 nm to 600 nm, 200 nm to 500 nm, 200 nm to 400 nm, or 200 nm to 300 nm.

The second segment comprises a core that is made of a material that can shrink after deposition in the template. Thus, the core has a smaller diameter than the first segment diameter. The core diameter can be 5 nm to 500 nm smaller than the diameter of the first segment. In some cases, the core diameter is 5 nm to 400 nm, 5 nm to 300 nm, 5 nm to 250 nm, 5 nm to 200 nm, 5 nm to 150 nm, 5 nm to 100 nm, 5 nm to 90 nm, 5 nm to 80 nm, 5 nm to 70 nm, 5 nm to 75 nm, 5 nm to 60 nm, 5 nm to 50 nm, 5 nm to 40 nm, 5 nm to 30 nm, 5 nm to 25 nm, 5 nm to 20 nm, 5 nm to 15 nm, or 5 nm to 10 nm smaller than the diameter of the first segment. In some cases, the core has a diameter of 35 nm to 150 nm.

In some cases, the difference in diameter between the core and the first segment is the same as the thickness of the shell. In cases where the template is widened after deposition of the core material, the shell thickness is thicker than the difference in diameter between the first segment and core (see, e.g., FIG. 1). The thickness of the shell can be 5 nm to 400 nm, 5 nm to 300 nm, 5 nm to 250 nm, 5 nm to 200 nm, 5 nm to 150 nm, 5 nm to 100 nm, 5 nm to 90 nm, 5 nm to 80 nm, 5 nm to 70 nm, 5 nm to 75 nm, 5 nm to 60 nm, 5 nm to 50 nm, 5 nm to 40 nm, 5 nm to 30 nm, 5 nm to 25 nm, 5 nm to 20 nm, 5 nm to 15 nm, or 5 nm to 10 nm.

In various cases, the diameter of the shell and core together can be 200 nm to 1 micron, 200 nm to 900 nm, 200 nm to 800 nm, 200 nm to 700 nm, 200 nm to 600 nm, 200 nm to 500 nm, 200 nm to 400 nm, 200 nm to 300 nm, 100 nm to 1 micron, 100 nm to 900 nm, 100 nm to 800 nm, 100 nm to 700 nm, 100 nm to 600 nm, 100 nm to 500 nm, 100 nm to 400 nm, 100 nm to 300 nm, or 100 nm to 200 nm.

In various cases, a temporary shell material is deposited in the template then the shell material. The temporary shell material is then removed (e.g., if nickel is the temporary shell material, the nickel can be dissolved), leaving a portion of the core exposed and not covered by the shell (see, FIG. 1). With multiple repeats of deposition of temporary shell material then shell material, followed by removal of the temporary shell material, the resulting shell material forms rings around the core material. The length of the rings and spacing between the rings is dictated by the controlled deposition of the shell material during, e.g., ECD, and the spacing between the rings (and between the first segment and the first ring) by controlled deposition of the temporary shell material during, e.g., ECD. Examples of temporary shell materials include, but are not limited to, nickel which is dissolved by nitric acid, and silver which is dissolved by a methanol/ammonia/hydrogen peroxide mixture. The number of shell rings, length of the shell rings, and spacing of the shell rings (e.g., two rings separated by a ring gap), on the nanorod can be tailored for the desired end use of the nanorod. The ring gap can be 3 nm to 100 nm, 3 nm to 90 nm, 3 nm to 80 nm, 3 nm to 70 nm, 3 nm to 75 nm, 3 nm to 60 nm, 3 nm to 50 nm, 3 nm to 40 nm, 3 nm to 30 nm, 3 nm to 25 nm, 3 nm to 20 nm, 3 nm to 15 nm, 3 nm to 10 nm, 5 nm to 100 nm, 5 nm to 90 nm, 5 nm to 80 nm, 5 nm to 70 nm, 5 nm to 75 nm, 5 nm to 60 nm, 5 nm to 50 nm, 5 nm to 40 nm, 5 nm to 30 nm, 5 nm to 25 nm, 5 nm to 20 nm, 5 nm to 15 nm, or 5 nm to 10 nm. The ring length can be 5 to 200 nm, 5 nm to 150 nm, 5 nm to 100 nm, 5 nm to 90 nm, 5 nm to 80 nm, 5 nm to 70 nm, 5 nm to 75 nm, 5 nm to 60 nm, 5 nm to 50 nm, 5 nm to 40 nm, 5 nm to 30 nm, 5 nm to 25 nm, 5 nm to 20 nm, 5 nm to 15 nm, 5 nm to 10 nm, 10 nm to 200 nm, 10 nm to 150 nm, 10 nm to 100 nm, 10 nm to 90 nm, 10 nm to 80 nm, 10 nm to 70 nm, 10 nm to 75 nm, 10 nm to 60 nm, 10 nm to 50 nm, 10 nm to 40 nm, 10 nm to 30 nm, 10 nm to 25 nm, 10 nm to 20 nm, or 10 nm to 15 nm.

The core material can be a semiconductor, a conjugated polymer, a metal oxide, a metal chalcogenide, or a mixture thereof. Nonlimiting examples of semiconductor materials contemplated include cadmium selenide, zinc selenide, cadmium telluride, zinc telluride, cadmium-tellurium selenide, copper-indium selenide, copper oxide, copper sulfide, silicon, germanium, compounds and alloys of silicon and germanium, gallium arsenide, gallium phosphide, gallium nitride, cadmium sulfide, zinc sulfide, titanium dioxide, zinc oxide, tungsten oxide, molybdenum oxide, manganese oxide, titanium sulfide, and mixtures thereof. In various cases, the core can comprise polythiophene, polypyrrole, titanium dioxide, manganese oxide, cadmium selenide, polyaniline, nickel, or a combination thereof. In some cases, the core comprises poly(3-hexylthiophene-2,5-diyl).

The shell (e.g., ring) material can be a metal. Nonlimiting examples of metals contemplated include gold, silver, nickel, platinum, palladium, or mixtures thereof. In cases where the nanorod comprises more than one ring, the ring material can be the same or different for each ring.

Also disclosed herein are second segments having a second shell over at least a portion of the first shell. In cases where the first shell is in the form of a ring, the second shell can be in direct contact with at least a portion of the core.

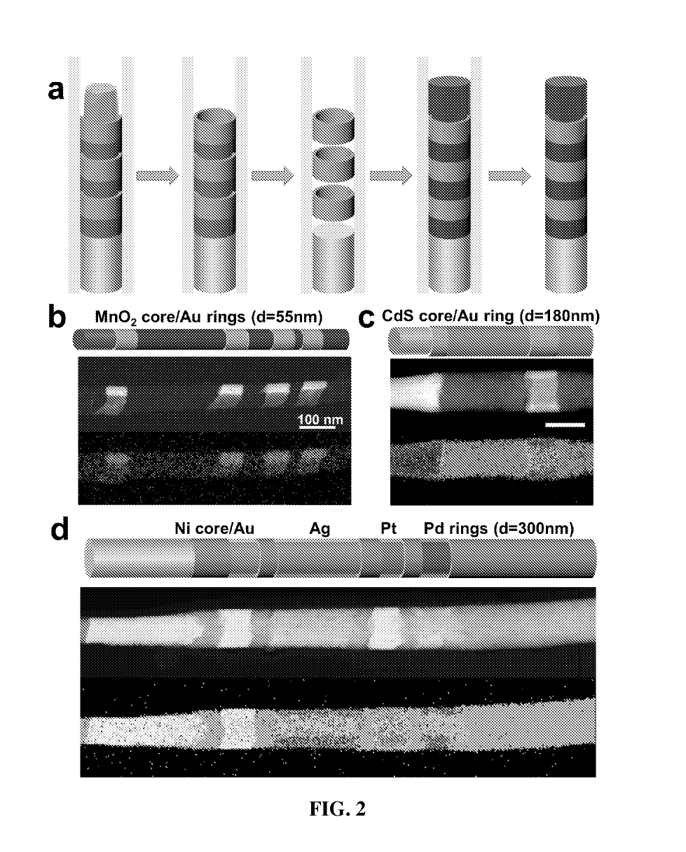

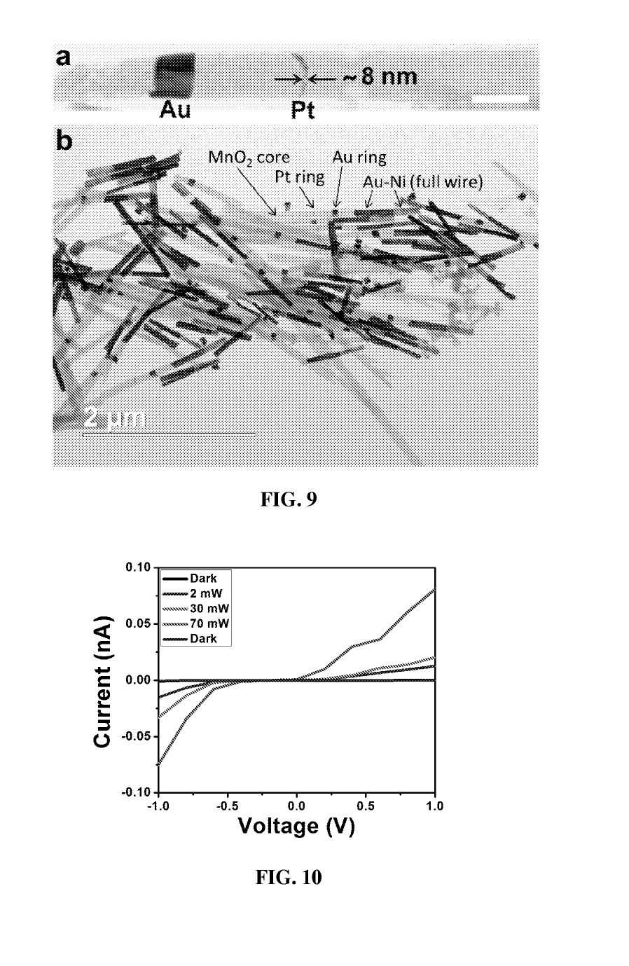

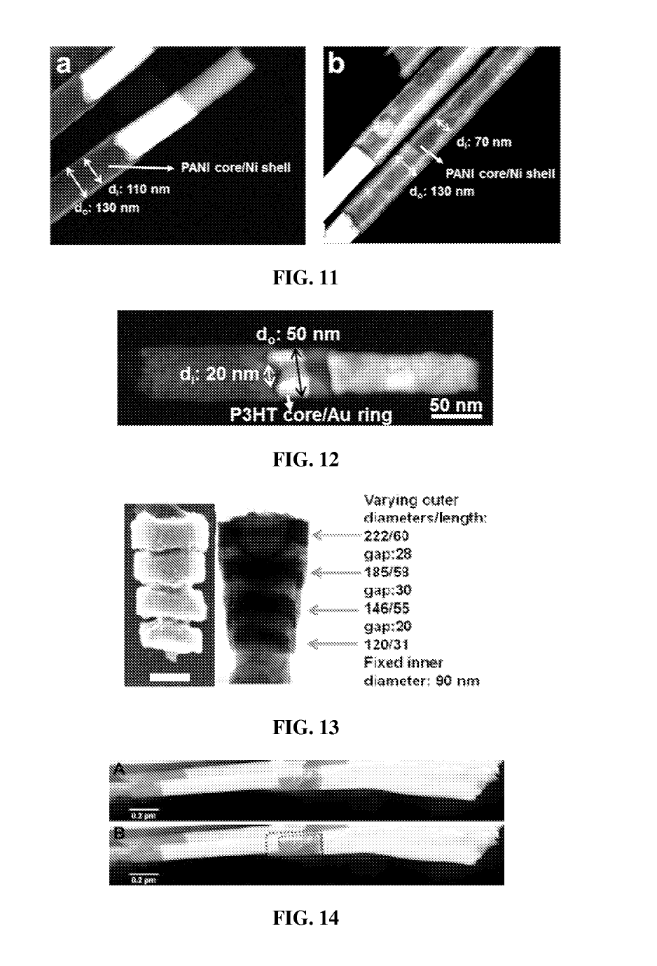

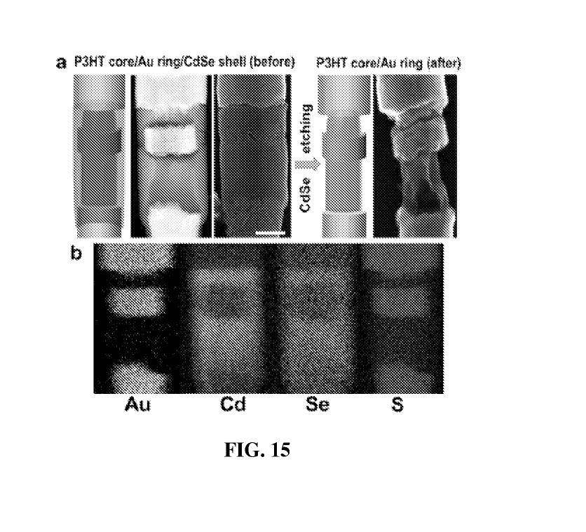

To generate core/shell nanowires with an inorganic core, an alternative pathway was developed (FIG. 2) by dissolving the polymeric core (polyaniline) in acetone and etching the sacrificial segments within the AAO membrane. In doing so, the rings are fixed inside the pores of the AAO membrane and remain at their original location throughout the entire process (FIG. 8). Subsequent electrodeposition occurs at the bottom of the pores, generating a nearly conformal contact between the core and shell segments. This pathway allows for the synthesis of coaxial nanowires with a core composed of practically any material that can be electrodeposited (organic, inorganic, metal or semiconductor), making COAL a highly versatile technique. To illustrate that point, several structures were synthesized composed of different inorganic cores (MnO₂, CdS and Ni) with well-defined metal nanorings. Elemental mapping via energy-dispersive X-Ray spectroscopy (EDS) confirms the formation of chemically pure rings around each of the nanowire cores. A variety of materials can be located as rings around an inorganic nanowire, as presented in FIG. 2D, showing the successful embedding of four distinct rings, composed of four different metals (Au, Pt, Ag and Pd) within the same nickel nanowire. Sub-10 nm control is possible in terms of shell length, as shown by the electron microscopy images (FIG. 9) of Au—Pt ring dimers embedded within MnO₂ nanowires with a Pt ring length of 8 nm (diameter: 80 nm).

To expand COAL to inorganic cores, an alternative pathway was developed (FIG. 2) by dissolving the core (e.g., polyaniline) in an appropriate solvent, e.g., acetone, and etching the sacrificial segments within the template, the AAO membrane. In doing so, the rings are fixed inside the pores of the template and remain at their original location throughout the entire process. Subsequent electrodeposition occurs at the bottom of the pores, generating a nearly conformal contact between the core and the shell-segments. This pathway allows for the synthesis of coaxial nanorods with a core comprising practically any material that can be electrodeposited (organic, inorganic, metal or semiconductor), making COAL a highly versatile technique. To illustrate that point, several structures composed of different inorganic cores (MnO₂, CdS and Ni) with well-defined metal nanorings were synthesized. Elemental mapping via energy-dispersive X-Ray spectroscopy (EDS) confirms the formation of chemically pure rings around each of the nanorod cores. A variety of materials can be located as rings around an inorganic nanorod, as shown in FIG. 2d, showing the successful embedding of four distinct rings, composed of four different metals (Au, Pt, Ag and Pd) within the same nickel nanorod. Sub-10 nm control is achieved in terms of shell length, as shown by the electron microscopy images of Au—Pt ring dimers embedded within MnO₂ nanorods with a Pt ring length of 10 nm (diameter: 50 nm).

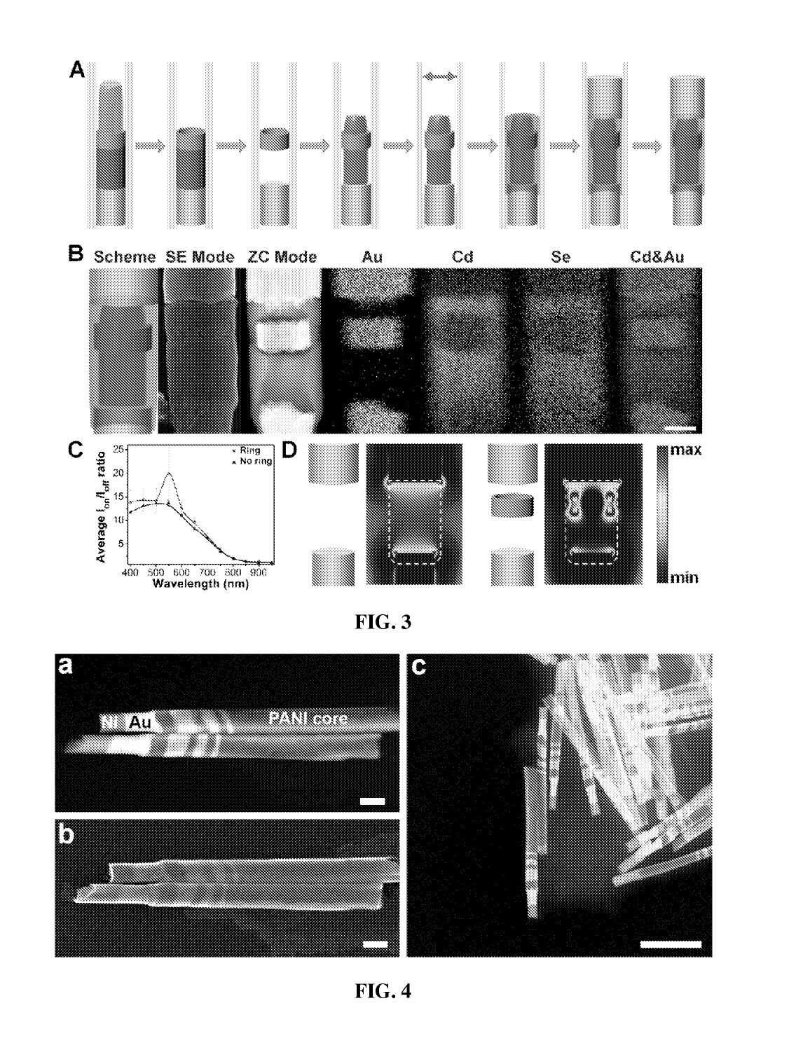

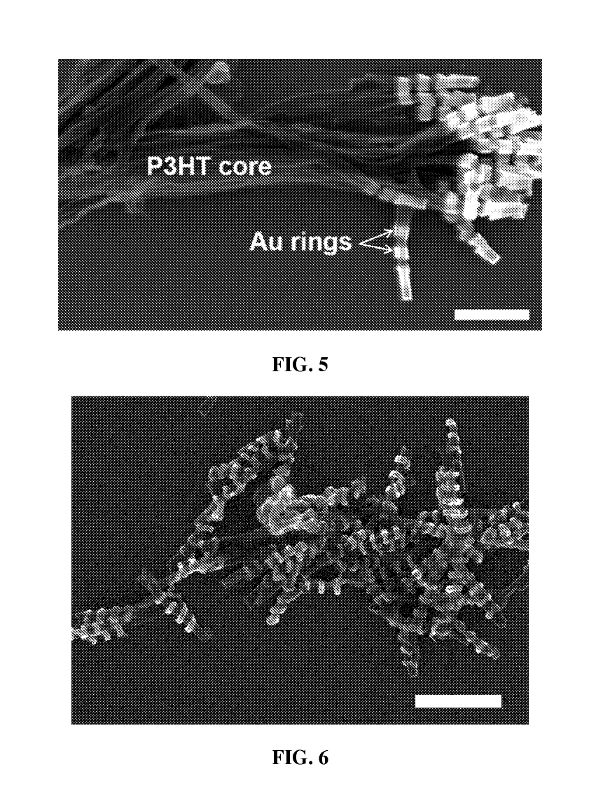

Finally, to demonstrate the structural complexity that can be achieved via COAL, a plasmonic gold nanoring within the radial p/n junction of a core/shell semiconductor nanowire was synthesized with a simple pore widening step (FIG. 3). Following the deposition of a gold nanoring around a p-type P3HT core within the AAO membrane (following the procedure presented in FIG. 2), the pores were widened using a 0.5 M NaOH aqueous solution. This creates room for the growth of the CdSe shell around the P3HT core and the Au ring (FIG. 3A). A z-contrast image of this nanowire along with elemental analysis (FIG. 3B) confirms the formation of a p-type core (P3HT)/shell (Au ring)/n-type shell (CdSe). The effect of the plasmonic ring was investigated by single nanowire electrical measurements. The nanowires were electrically addressed using electron-beam lithography, measured under vacuum, and irradiated with monochromatic light using a monochromator and a xenon lamp. The plasmonic ring strongly modifies the photoresponse of the nanowires (FIG. 3C). The P3HT/CdSe nanowires (with and without ring) showed Schottky diode behavior (FIG. 10) and significant photocurrent generation under monochromatic light excitation. The current was measured under 1V bias with (Iₒₙ) and without (I_{off}) illumination, and the photodetection ability of the nanowires was defined by the ratio Iₒₙ/I_{off}. The reference nanowire (without a ring) showed a reproducible response: Iₒₙ/I_{off} ratio of 13.6±0.6 at 550 nm under ˜40 μW/cm⁻² light power. The hybrid nanowires (with a ring) were not as consistent with few wires having very low Iₒₙ/I_{off} ratios, which can be attributed to the weaker Au—CdSe junction around the Au ring, leading to some discontinuous/broken CdSe junctions during the post-synthetic sample preparation steps. However, once these wires were discarded, the average Iₒₙ/I_{off} ratio was much higher (average of three nanowires for each case, with and without a ring). Increase of the photoresponse over the entire visible spectrum was observed with a maximum around 550 nm (average Iₒₙ/I_{off} ratio of 19.9±5.6), corresponding to an average ˜45% increase in Iₒₙ/I_{off} ratio. The spectral photoresponse of the diode was also modified by the presence of the plasmonic ring, as shown in FIG. 3C, which is characteristic of plasmon-enhanced absorption (4, 8). This is supported by finite difference time-domain (FDTD) simulations (FIG. 3D), which shows that the electric field intensity is greatly increased within and around the gold ring at 532 nm (for simplicity, the semiconductor segment was not included in the model, however, a red shift is expected due to the higher dielectric constants of the semiconductors). These measurements demonstrate that the nanowires synthesized by COAL can be used to prepare nanoscale functional devices, and can be used to investigate the optoelectronic properties of nanostructures with complex geometries, which cannot be made by any other means.

Provided herein are novel techniques bridging templated synthesis and lithography to generate nanorods in a parallel fashion with an unprecedented structural control. COAL does not require costly instrumentation such as clean-room lithography equipment, and is compatible with metals, metal sulfides, metal selenides, metal oxides, and organic semiconductors. In a field often limited by the availability of synthetic tools, the advances herein pave the way for a rich series of experiments that will explore fundamental light-matter interactions and break new ground in nanowire based electronic device research. The large flexibility offered by COAL in terms of geometry, dimension and composition is expected to be very successful at improving nanorod efficiencies in areas such as photovoltaics, photocatalysis and energy storage. In particular, the study of plasmon-enhanced processes should greatly benefit from the synthetic capabilities provided by COAL, as demonstrated by the successful synthesis of plasmonic nanorings within p-n type core/shell semiconductor nanowires.

### Examples

### Materials and Chemicals

All chemicals and solutions were used without further processing. Commercially available plating solutions (Cyless for Ag, Orotemp 24 Rack for Au, Pallaspeed VHS for Pd, and nickel sulfamate for Ni) were purchased from Technic Inc., USA. Thiophene (≧99%), 3-hexylthiophene (≧99%), cadmium sulfate (99%), lithium perchlorate (99.99%), selenium dioxide (99.9%), boron trifluoride diethyl etherate, cadmium chloride (99.99%), sulfur (≧99.5%), dimethyl sulfoxide (≧99%), aniline (≧99.5%), potassium hydroxide (≧99%), concentrated perchloric acid (≧99.999%), nitric acid (ACS grade), ammonium hexachloroplatinate (99.999%), sodium phosphate dibasic (99%), sulfuric acid (ACS grade) and sodium citrate (≧99%) were purchased from Sigma Aldrich, USA. Manganese acetate was obtained from Alfa. Nanopure™ water was used. Porous anodized aluminum oxide (AAO) membranes with nominal pore diameters of 280 nm were purchased from Whatman Inc., USA. AAO membranes with 35, 55 and 100 nm nominal pore diameters were purchased from Synkera Technologies Inc., USA.

### Instruments

Secondary electron (SE mode) and high-angle annular dark-field imaging z-contrast (ZC mode) scanning transmission electron microscope (STEM) images were acquired using a Hitachi HD-2300 STEM. Electrochemical deposition of metals and inorganic semiconductors were done using a BASi EC epsilon potentiostat (Bioanalytical Systems, Inc., USA). Extinction spectra were collected in aqueous solutions using quartz cuvettes (1 cm path length) and a Varian Cary 5000 UV-Vis-NIR spectrophotometer. Instruments used for the single nanowire measurements are described later in the text.

### Nanowire Synthesis

Porous anodised aluminium oxide (AAO) membranes were coated with a 200 nm thick Ag layer and used as templates to synthesise nanowires in a three electrode setup, as disclosed, e.g., in ref. 17. Ag, Ni and then Au were successively electrodeposited within the AAO membrane. Next, the polymer core was deposited and the samples were vacuum dried for 30 minutes to create empty spaces between the polymer segment and the wall of the AAO pore. This space was filled with alternating layers of the metals of interest to generate a multi-segmented shell around the polymeric core. For example, the nanowires shown in FIG. 1c were produced by using sacrificial Ni rings, while Au was used as the target material to create Au rings around a PPy core. Additionally, to control the outer diameter of the nanorings and/or synthesize core/shell/shell nanowires, a simple pore-widening step was performed by exposing the membrane to 0.5 M NaOH (from 1 to 20 minutes). Pore-widening was done after the deposition of the first shell segment to fabricate a core-shell-shell nanowire, such as the nanowire shown in FIG. 1d. Alternatively, to generalize the COAL process to non-shrinking inorganic materials, the polymer core was dissolved in a suitable solvent following the shell deposition, sacrificial metal segments were etched in the AAO membrane, and the inorganic material was deposited. For example, the nanowire shown in FIG. 2a was composed of a PANI core with alternating shell segments of Ni and Au. After the Au/Ni shell deposition, the PANI core was dissolved by immersing in acetone for 6 hours. The Ni shell segments were then etched by immersing the top of the AAO membrane in a 3% FeCl₃ aqueous solution for 1 hour. The inorganic core (MnO₂) was then deposited under constant potential. Furthermore, a combination of the approaches described above was used for the integration of metal nanorings within a core-shell semiconductor nanowire, such as the nanowire shown in FIG. 3. Following the deposition of a Ag—Ni—Au multisegmented nanorod, PANI was electropolymerized and dried under vacuum for 30 minutes. Alternating segments of Ni and Au were deposited. PANI was dissolved by immersing in acetone for 6 hours and the sacrificial Ni segments were etched by immersing the AAO membrane in a 3% FeCl₃ aqueous solution for 1 hour. The membrane was then dried under vacuum for 30 minutes. The P3HT was then electropolymerized through the Au ring. Pore-widening was then performed to create room for the growth of the CdSe shell. After the CdSe deposition a final Au segment was deposited to create the top Au electrode. Following the deposition of the nanowires, the Ag backing layer was etched in a 4:1:1 ethanol:ammonium hydroxide:hydrogen peroxide solution for 20 minutes. The AAO membrane was then dissolved in 0.5 M NaOH for 10 minutes to release the nanowires. Nanowires were spun down for 4 minutes at 2000-7500 rpm, depending on the nanowire diameter (inversely proportional). The wires were then rinsed 3 times in H₂O (0.1% sodium citrate by weight). Finally, the sacrificial segments were etched when necessary and the nanowires were then washed and spun down three times.

### Electrochemical Depositions

Metals: Metals were deposited at constant potentials using aqueous plating solutions. Au was deposited at −930 mV (280 and 100 nm template) and −1100 mV (55 and 35 nm template) using Orotemp 24 Rack solution. Ag was deposited at −900 mV using Cyless solution. Pd was deposited at −900 mV using Pallaspeed VHS solution. Nickel was deposited at −930 mV (280 nm and 100 nm template) and −1100 mV (55 and 35 nm template). Pt was deposited at −520 mV using a homemade aqueous Pt solution (15 mM (NH₄)₂PtCl₆ and 200 mM Na₂HPO₄).

Polypyrrole (PPy): PPy was deposited at +750 mV, using a homemade solution containing 510 μL of pyrrole dissolved in 30 mL of a 0.1 M LiClO₄ aqueous solution.

Polyaniline (PANI): PANI was deposited at +1000 mV, using a homemade solution containing 680 μL of aniline dissolved in a 0.1 M HClO₄ aqueous solution.

Polythiophene (PTh) and poly(3-hexylthiophene) (P3HT): PTh and P3HT were deposited using cyclic voltammetry between −400 and +1100 mV at 400 mV/s. A Pt rod was used as the counter electrode. The monomers were dissolved in boron trifluoride diethyl etherate (BFEE) which served as the solvent and the electrolyte (10, 30, 31). Prior to the deposition, the electrochemical cell and the AAO membrane were immersed in ethanol and dried under vacuum to remove any residual water.

CdSe: CdSe was deposited as previously reported using cyclic voltammetry between −387 and −787 mV vs SCE at 752 mV/s (32). The plating solution was composed of 0.7 mM SeO₂, 0.3 M CdSO₄, and 0.25 M H₂SO₄. Triton X (0.25% v/v) was added to the solution.

CdS: CdS was deposited as previously under constant current (−1.5 mA.cm⁻²) at 130° C. in a two electrode configuration (21). A Pt mesh was used as the counter electrode. The plating solution was made by dissolving 1.52 g of CdCl₂ and 914 mg of S in hot DMSO.

MnO₂: MnO₂ was deposited according to the literature at +750 mV using an aqueous solution of manganese acetate (49 mg of manganese acetate was dissolved in 20 mL of water) (33).

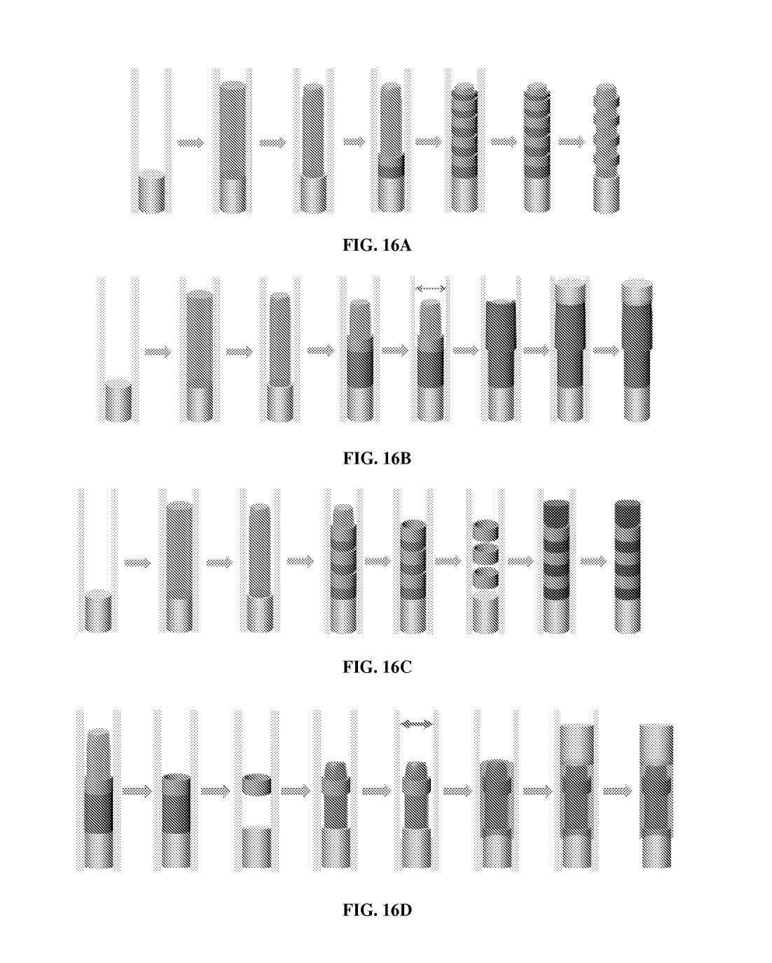

Following the deposition of the metal segments as shown in FIG. 16A, the polymer core was deposited. The samples were vacuum dried for 30 minutes to create empty spaces between the polymer segment and the wall of the AAO pore. This space was filled up with alternating layers of the metals of interest to generate a multi-segmented shell around the polymeric core. For example, the nanowires shown in FIG. 1b were produced by using sacrificial Ni rings, while Au was used as the target material to create Au rings around a PPy core. Following the deposition of the nanowire, the Ag backing layer was etched in a 4:1:1 ethanol:ammonium hydroxide:hydrogen peroxide solution for 20 minutes. The AAO membrane was then dissolved in 0.5 M NaOH for 10 minutes under continuous shaking to release the nanowires. Nanowires were spun down 4 minutes at 2000-7500 rpm depending on the nanowire diameter (soft acceleration and deceleration mode of an Eppendorf 5417R microcentrifuge). Lower spinning speeds were used for the large diameter wires to avoid unwanted breaking. The wires were then rinsed 3 times in H₂O (0.1% sodium citrate by weight). Finally, the sacrificial segments were etched (when using a sacrificial Ni shell segments, a 50% nitric acid aqueous solution was used for 10 minutes). The nanowires were then washed and spun down three times as previously described.

Synthesis of the Ag—Ni—Au-polymer nanowires was performed as described in approach #1. Following the polymer core deposition step, the membrane was vacuum dried for 30 minutes. Pore widening, as generally shown in FIG. 16B, was performed by exposing the membrane to 0.5 M NaOH. The outer diameter of the nanoring was controlled by the pore widening time (from 1 to 20 minutes). Similarly, pore widening can be done after the deposition of the first shell segment to fabricate a core-shell-shell nanowire, such as the nanowire shown in FIG. 1b.

Synthesis of the Ag—Ni—Au-PANI nanowires with the desired shell segments was performed as described in approach #1 as generally shown in FIG. 16C. Following the shell deposition, the polymer core was dissolved in a suitable solvent, sacrificial metal segments were etched in the AAO membrane, and the inorganic material was finally deposited. For example, the nanowire shown in FIG. 2A was composed of a PANI core (pore diameter: 55 nm) with alternating shell segments of Ni and Au. After the Au/Ni shell deposition, the PANI core was dissolved in acetone for 6 hours (the acetone solution was exchanged several times). The Ni shell segments were then etched by immersing the top of the AAO membrane in a 3% FeCl₃ aqueous solution for 1 hour. The inorganic core (composed of MnO₂) was then deposited under constant potential. Nanowires were released into the solution as described above.

A combination of the approaches described above was used to fabricate the nanowire shown in FIG. 3, as shown in FIG. 16D. Following the deposition of a Ag—Ni—Au multisegmented nanorod, PANI was electropolymerized and dried under vacuum for 30 minutes in the pores of the AAO membrane (pore diameter: 100 nm). Alternating segments of Ni and Au were successively deposited. PANI was dissolved in acetone for 6 hours and the sacrificial Ni segments were etched by immersing the AAO membrane in a 3% FeCl₃ aqueous solution for 1 hour. The membrane was then dried under vacuum for 30 minutes prior to the deposition of the P3HT core to remove any residual solvent. The P3HT was then electropolymerized, and grows through the Au ring. Pore widening is then performed to create room for the growth of the CdSe shell, while the location of the Au ring is maintained due to the very strong mechanical bond between the polymeric core and the Au ring. After the CdSe deposition, which grows around the P3HT core and the Au ring, a final Au segment is deposited on top to create the top Au electrode. Nanowires were released into the solution using the same procedure described in the approach outlined in FIG. 16A.

### Photolithography and E-Beam Lithography

Si wafer with a 500 nm oxide coating was spin-coated at 500 rpm for 10 s and at 4000 rpm for 40 s with a layer of S1805 photoresist (Shipley, USA) and was annealed at 115° C. for 1 min. Patterning on the resist was made using a Microtech MA6 Aligner mask aligner (Suss, Germany) and the patterns were developed with MF-24A (Microchem, USA) for 1 min. For the electrode pads 5 nm Cr and 100 nm of Au were evaporated and the photoresist and excess metal layer was lifted off using Remover PG (Microchem, USA) for overnight. Multi-segmented nanowires were drop-casted on the patterned Si chips on a hot plate at 70° C. and left for drying for 5 minutes. Metal electrodes on the Si chip and the nanorod electrode segments on the nanowires were bridged using Quanta FESEM (FEI, USA) electron beam lithography (EBL). Si wafer with well dispersed nanowires was spin-coated at 500 rpm for 10 s and at 3000 rpm for 45 s with a layer of 950 PMMA C7 e-beam resist (Microchem, USA) and annealed at 180° C. for 2 min. Fine patterning was done using the Nanometer Pattern Generation System (NPGS, JC Nabity Lithography System, Bozeman, Mont., USA) at 30 kV acceleration voltage and the patterns were developed with 3:1 IPA/MIBK solution for 1 min. 3 nm of Cr and 75 nm of Au films were evaporated and the excess materials were lifted off overnight in acetone.

### Electrical Characterization

The electrical characterizations were carried under vacuum (˜10⁻⁵ Torr) using a Keithley 4200-SCS semiconductor characterization system. Current-voltage characterizations on single nanowires were performed under dark and under light illumination using the built-in microscope lamp as the illumination source. Schottky diode behavior was observed for the P3HT core-CdSe shell nanowires, with and without the Au nanoring (FIG. 10).

A 300 W xenon light source was passed through an Oriel 1/8 m 77250 monochromator and the monochromatic output light was carried onto the sample with a fiber optic cable to serve as the excitation source for the spectral photocurrent measurements. The output power was measured using a S130C slim photodiode power sensor connected to PM200 power and energy meter console (Thorlabs) at collection wavelength matching the value set on the monochromator. Nanowires were exposed to monochromatic light for 10 s in between 400-900 nm with 50 nm steps. There was a 45 s delay in between each measurement to give enough time for relaxation of the excited carriers. Top three values recorded during light exposure was averaged and divided by the current value under dark to calculate the light on/light off ratio for each measurement. The Iₒₙ/I_{off} ratios were plotted as a function of wavelength. The top three performing nanowires from each set (with and without rings) were averaged and plotted in FIG. 3C.

### Simulations

Electric fields generated by the core-shell-ring nanowires were calculated using a commercially available finite-difference-time-domain (FDTD) simulation software package developed by Lumerical Solutions Inc., Vancouver, Canada. Nanowires were excited by a total field scattered field (TFSF) plane wave source with light injected in z-axis with polarization in x-axis in between 500-900 nm spectral range. The refractive index of the medium was set to 1 since the electrical measurements were done under vacuum. Electric field simulations were done in 3D and 0.25 nm resolution (mesh size) was used for the calculations. Optical parameters were used from the materials library of Lumerical Software for different segments of the nanowires (Johnson and Christy data was used directly from the Lumerical materials library for Au segments).

To show the effect of enhanced electric fields directed into the semiconducting region, electric field intensity maps were generated with the use of an excitation source polarized in the direction parallel to the longitudinal axis of the nanowires. Note that the experimental extinction spectra are slightly different than the simulated extinction spectra. This is due to the fact that the experimental measurements were done in solution and were thus averaged over all the different polarizations, whereas the simulations were done with only one polarization (parallel to the longitudinal axis of the nanowires). Also, the plasmon resonance peaks were broader in the experimental spectra owing to the size distribution of the nanowires.

### Elemental Mapping

EDS mapping was performed using a Hitachi HD-2300 STEM equipped with two EDS Oxford detectors.

For the MnO₂/Au nanowire presented in FIG. 2b, the Au Mal line at 2.122 keV (integration: 2.014 to 2.230 keV) and the Mn Kα line at 5.895 keV (integration: 5.746 to 6.044 keV) were used.

For the CdS/Au nanowire presented in FIG. 2c, the Au Lα1 line at 9.712 keV (integration: 9.726 to 10.042 keV) and the Cd Lα1 line at 3.133 keV (integration: 3.010 to 3.256 keV) were used.

For the Ni/Au/Ag/Pt/Pd nanowire presented in FIG. 2d, the Ni Lα1 line at 0.851 keV (integration: 0.754 to 0.948 keV), Au Mal line at 2.122 keV (integration: 2.014 to 2.230 keV), Ag Lα1 line at 2.984 keV (integration: 2.862 to 3.106 keV), Pt Lα1 line at 9.441 keV and Pt Lα2 line at 9.360 keV (integration: 9.251 to 9.528 keV) and Pd Lα1 line at 2.838 keV (integration: 2.718 to 2.958 keV) were used.

As can be seen in FIG. 2d, there is some overlap between the Au and Pt signals due to some overlap between the Au Lα2 line (9.626 keV) and the Au Mal line (2.122 keV) with the Pt Lα1 line (9.441 keV) and the Pt Mal line (2.050 keV), respectively.

For similar reasons, there is some overlap between the Ag and the Pd signals due to the some overlap between the Ag Lα1 line at 2.984 keV and the Pd Lα1 line at 2.838 keV. The rings were made of pure element as verified by doing point EDS measurements.

For the P3HT core-Au ring-CdSe shell nanowire shown in FIG. 3b, the Au Lα1 line at 9.712 keV (integration: 9.726 to 10.042 keV), Cd Lα1 line at 3.133 keV (integration: 3.010 to 3.256 keV), and Se Lα1 line at 1.379 keV (integration: 1.275 to 1483 keV) were used.

For clarity and due to the overlap between the Au Mβ,γ lines (2.204 and 2.410 keV, respectively) and the S Kα line (2.307 keV), the sulfur maps originating from the CdS core (FIG. 2c) and the P3HT core (FIG. 3b) were not included.

### REFERENCES

1. E. Ozbay, Plasmonics: Merging photonics and electronics at nanoscale dimensions. Science 311, 5758 (2006).
2. J. A. Schuller, E. S. Barnard, W. Cai, Y. C. Jun, J. S. White, M. L. Brongersma, Plasmonics for extreme light concentration and manipulation. Nat. Mater. 9, 193 (2010).
3. M. E. Stewart, C. R. Anderton, L. B. Thompson, J. Maria, S. K. Gray, J. A. Rogers, R. G. Nuzzo, Nanostructured plasmonic sensors. Chem. Rev. 108, 494 (2008).
4. H. A. Atwater, A. Polman, Plasmonics for improved photovoltaic devices. Nat. Mater. 9, 205 (2010).
5. S. Linic, P. Christopher, D. B. Ingram, Plasmonic metal nanostructures for efficient conversion of solar to chemical energy. Nat. Mater. 10, 911 (2011).
6. A. S. Arico, P. Bruce, B. Scrosati, J. M. Tarascon, W. van Schalkwijk, Nanostructured materials for advanced energy conversion and storage devices. Nat. Mater. 4, 366 (2005).
7. J. Wallentin, N. Anttu, D. Asoli, M. Huffman, I. Aberg, M. H. Magnusson, G. Siefer, P. Fuss-Kailuweit, F. Dimroth, B. Witzigmann, H. Q. Xu, L. Samuelson, K. Deppert, M. T. Borgstrom, InP nanowire array solar cells achieving 13.8% efficiency by exceeding the ray optics limit. Science 339, 1057 (2013).
8. J. Tang, Z. Huo, S. Brittman, H. Gao, P. Yang, Solution processed core-shell nanowires for efficient photovoltaic cells. Nat. Nanotechnol. 6, 568 (2011).
9. C. E. Garnett, M. L. Brongersma, Y. Cui, M. D. McGehee, Nanowire solar cells. Annu. Rev. Mater. Res. 41, 269 (2011).
10. G. Bourret, T. Ozel, M. Blaber, C. Shade, G. C. Schatz, C. A. Mirkin, Long-range plasmophore rulers. Nano Lett. 13, 2270 (2013).
11. R. A. Pala, J. S. Q. Liu, E. S. Barnard, D. Askarov, E. C. Garnett, S. Fan, M. L. Brongersma, Optimization of non-periodic plasmonic light-trapping layers for thin-film solar cells. Nat. Commun. 4, 2095 (2013).
12. S. Mubeen, G. Hernadez-Sosa, D. Moses, J. Lee, M. Moskovits, Plasmonic photosensitization of a wide band gap semiconductor: converting plasmons to charge carriers. Nano Lett. 11, 5548 (2011).
13. S. Mubeen, J. Lee, N. Singh, S. Kramer, G. D. Stucky, M. Moskovits, An autonomous photosynthetic device in which all charge carriers derive from surface plasmons. Nat. Nanotechnol. 8, 247 (2013).
14. H. Gao, C. Liu, H. E. Jeong, P. Yang, Plasmon enhanced photocatalytic activity of iron oxide on gold nanopillars. ACS Nano 6, 234 (2012).
15. R. D. Piner, J. Zhu, F. Xu, S. Hong, C. A. Mirkin, Dip-pen nanolithography. Science 283, 661 (1999).
16. S. Y. Chou, P. R. Krauss, P. J. Renstrom, Imprint lithography with 25-nanometer resolution. Science 272, 85 (1996).
17. L. Qin, S. Park, L. Huang, C. A. Mirkin, On-wire lithography. Science 309, 113 (2005).
18. I. Thomann, B. A. Pinaud, Z. Chen, B. M. Clemens, T. F. Jaramillo, M. L. Brongersma, Plasmon enhanced solar-to-fuel energy conversion. Nano Lett., 11, 3440 (2011).
19. B. Tian, X. Zheng, T. J. Kempa, Y. Fang, N. Yu, G. Yu, J. Huang, C. M. Lieber, Coaxial silicon nanowires as solar cells and nanoelectronic power sources. Nature 449, 885 (2007).
20. D. C. Dillen, K. Kim, E. Liu, E. Tutuc, Radial modulation doping in core-shell nanowires. Nat. Nanotechnol. 9, 116 (2014).
21. D. Routkevitch, T. Bigioni, M. Moskovits, J. M. Xu, Electrochemical fabrication of CdS nanowire arrays in porous anodic aluminum oxide templates. J. Phys. Chem. 100, 14037 (1996).
22. C. R. Martin, Nanomaterials: A membrane-based synthetic approach. Science 266, 1961 (1994).
23. B. R. Martin, D. J. Dermody, B. D. Reiss, M. Fang, L. A. Lyon, M. J. Natan, T. E. Mallouk, Orthogonal self-assembly on colloidal gold-platinum nanorods. Adv. Mater. 11, 1021 (1999).
24. S. R. Nicewarner-Pena, R. G. Freeman, B. D. Reiss, L. He, D. J. Pena, I. D. Walton, R. Cromer, C. D. Keating, M. J. Natan, Submicrometer metallic barcodes. Science 294, 137 (2001).
25. T. Mirkovic, M. L. Foo, A. C. Arsenault, S. Fournier-Bidoz, N. S. Zacharia, G. A. Ozin, Hinged nanorods made using a chemical approach to flexible nanostructures. Nat. Nanotechnol., 2, 565 (2007).
26. M. J. Banholzer, L. Qin, J. E. Millstone, K. D. Osberg, C. A. Mirkin, On-wire lithography: Synthesis, encoding, and biological applications of metal nanodisks and nanorods. Nat. Protoc. 4, 838 (2009).
27. K. D. Osberg, A. L. Schmucker, A. J. Senesi, C. A. Mirkin, One-dimensional nanorod arrays: Independent control of composition, length, and interparticle spacing with nanometer precision, Nano Lett., 11, 820 (2011).
28. W. Wei, S. Z. Li, J. E. Millstone, M. J. Banholzer, X. D. Chen, X. Y. Xu, G. C. Schatz, C. A. Mirkin, Surprisingly long-range surface-enhanced raman scattering (SERS) on Au—Ni multisegmented nanowires, Angew. Chem. Int. Ed. 48, 4210 (2009).
29. S. H. Liu, J. B. H. Tok, Z. N. Bao, Nanowire lithography: Fabricating controllable electrode gaps using Au—Ag—Au nanowires. Nano Lett. 5, 1071 (2005).
30. T. Ozel, G. Bourret, A. Schmucker, K. Brown, C. A. Mirkin, Hybrid semiconductor core-shell nanowires with tunable plasmonic nanoantennas. Adv. Mater. 25, 4515 (2013).
31. D. M. O'Carroll, C. E. Hofmann, H. A. Atwater, Adv. Mater. 22, 1223 (2010).
32. M. Schierhorn, S. W. Boettcher, S. Kraemer, G. D. Stucky, M. Moskovits, Photoelectrochemical performance of CdSe nanorod arrays grown on a transparent conducting substrate. Nano Lett. 9, 3262 (2009).
33. R. Liu, S. B. Lee, MnO₂/Poly(3,4-ethylenedioxythiophene) coaxial nanowires by one-step coelectrodeposition for electrochemical energy storage. J. Am. Chem. Soc. 130, 2942 (2008).

1. A nanorod comprising a first segment and a second segment, the first segment comprising a metal and the second segment comprising (a) a core having a diameter smaller than the first segment diameter, and optionally (b) a shell around at least a portion of the core, the first segment in contact with the core.

2. The nanorod of claim 1, wherein the shell is absent.

3. The nanorod of claim 1, wherein the shell length is the same as the core length.

4. (canceled)

5. The nanorod of claim 1, wherein the shell abuts the first segment.

6. The nanorod of claim 1, wherein the shell is separated from the first segment by a gap.

7. The nanorod of claim 1, wherein the shell forms a ring around the core and has a ring length, said ring length shorter than the core length.

8. The nanorod of claim 7, having at least two rings around the core, each ring on the core separate by a ring gap.

9. (canceled)

10. The nanorod of claim 8, wherein each ring comprises the same material.

11. The nanorod of claim 8, wherein each ring comprises a metal.

12. (canceled)

13. The nanorod of claim 8, wherein one ring comprises a first ring material and another ring comprises a second ring material.

14. The nanorod of claim 13, wherein the first ring material comprises gold and the second ring material comprises silver, platinum, or nickel.

15. (canceled)

16. The nanorod of claim 7, wherein the ring length is about 10 nm to about 100 nm.

17.-18. (canceled)

19. The nanorod of claim 1, wherein the core has a diameter of about 35 to about 150 nm.

20. The nanorod of claim 1, wherein the shell and core together have a diameter of about 200 nm to about 700 nm.

21. (canceled)

22. The nanorod of claim 1, wherein the core comprises a semiconductor.

23.-26. (canceled)

27. The nanorod of claim 1, wherein the shell comprises nickel, gold, silver, platinum, palladium, or a mixture thereof.

28. The nanorod of claim 1, further comprising a third segment, the second segment separating the first segment and the third segment.

29.-31. (canceled)

32. The nanorod of claim 1, further comprising a second shell over the core and shell of the second segment.

33.-34. (canceled)

35. A method of making the nanorod of claim 1 comprising:
a) depositing the first segment onto a template using electrochemical deposition (ECD), and controlling the length of the first segment by monitoring the amount of charge passed during the electrochemical deposition;
b) depositing the core of the second segment using ECD, and controlling the length of the core by monitoring the amount of charge passed during the ECD;
c) optionally depositing the shell using ECD;
d) optionally repeating one or more of steps (b) and (c);
e) optionally widening the template prior to the depositing of step (c); and
e) dissolving the template to form the nanorod.

36. Use of the nanorod of claim 1 as a semiconductor, as an energy storage device, in solar energy conversion, in photovoltaics, or in photocatalysis.
